(19) United States
(12) Patent Application Publication
(10) Pub. No.: US 2010/0123477 A1
(43) Pub. Date: May 20, 2010

(54) PROGRAMMABLE ARRAY MODULE

(76) Inventor: Shih-Wei Sun, Taipei City (TW)

Correspondence Address: NORTH AMERICA INTELLECTUAL PROPERTY CORPORATION, P.O. BOX 506, MERRIFIELD, VA, 22116, US

(21) Appl. No.: 12/275,203

(22) Filed: Nov. 20, 2008

(51) Int. Cl. H03K 19/177

(52) U.S. Cl. 326/41

(57) ABSTRACT

A programmable array module includes a base circuit including an interface circuit and multiple layers of field programmable gate array (FPGA) disposed on and electrically connected to the base circuit.

### BACKGROUND OF THE INVENTION

1. Field of the Invention

The present invention relates to a programmable array module. In particular, the present invention relates to a multiple-layer stacking programmable array module.

2. Description of the Prior Art

With the quick development of the industrial techniques, the application-specific integrated circuit (ASIC) faces more and more challenges to meet the demand of being more and more powerful, being less and less energy-consuming as well as having shorter and shorter life cycles. However, the traditional chip design methods can no longer cope with the more and more demanding applications. System-on-a-chip (SoC) becomes so popular because of its advantages of high integration and low power consumption.

In addition to the current IC microprocessors, there is another commercially available processing element, which has the quality of being “reconfigurable.” Such reconfigurable processing element exhibits various flexibility and features in many aspects relative to the current application-specific integrated circuit. This reconfigurable processing element is generally known as the field programmable gate array (FPGA).

The field programmable gate array is a circuit which is capable of changing its configuration over and over again. This kind of logic gate element which is re-programmable in accordance with the demands of the users is especially suitable for use in the products which is required to repeatedly change its designs during its development stage to effectively accelerate the speed to enter the market. The characters of the logic gates of the field programmable gate array are changeable according to the commands of the users' and provide various basic functions. The current traditional application-specific integrated circuit chips are mostly composed of multiple layers of circuits. Each layer of circuit requires a reticle which is especially designed and independently made for a specific and corresponding process step. Generally speaking, each chip requires many reticles for use in the production stage to obtain a complete chip.

In the old method for the application-specific integrated circuit, each layer of circuit requires a corresponding reticle. It is well known that the design cost and the manufacturing cost for the reticles are enormous. Massively produced chips can no longer catch up with the fast moving market which always calls for quick response to the trend. Unfortunately, the circuit design of the traditional application-specific integrated circuit is bound by the pre-determined reticles. It is too slow and too expensive to make the change practically possible. However, the field programmable gate array is so flexible, like re-combinable letters, that its logic configuration can be reconstructed quickly enough in response to different applications. Most circuit-fixed logic chips and microprocessors can not be re-designed but it is not true for the field programmable gate array.

However, the field programmable gate array itself also has a very serious problem, that is, extremely low tolerance to the unavoidable defected elements certainly occurred during the production. Unlike the random access memory which can be fixed by redundancy to replace any defected elements to keep a normal performance, for an n*n field programmable gate array, any defected element means a total failure of the entire field programmable gate array. Considering this, the yield of the field programmable gate array is being deemed unacceptably low for a long time, and the production cost is therefore dramatically high because of the low yield.

Accordingly, a novel programmable array module is needed. After practically taking the unavoidable defected elements occurred in the production into consideration, the novel programmable array module should have dramatically high yield and low production cost to be advantageously competitive.

### SUMMARY OF THE INVENTION

The present invention therefore proposes a novel programmable array module. After practically taking the unavoidable defected elements occurred in the production into consideration, the novel programmable array module of the present invention still has dramatically high yield and low production cost to be advantageously competitive in the presence of the undesirable defected elements. In addition, as many as possible programmable logic gates can be accommodated in a single limited chip area to magnify the compute ability of the novel programmable array module of the present invention as much as possible to be nearly optimal. It is another feature of the novel programmable array module of the present invention.

The present invention first proposes a programmable array module. The programmable array module includes a base circuit element and a plurality of core circuit elements. The base circuit element includes an interface circuit, which is further electrically connected to a computer system. The plurality of core circuit elements are stacking over and electrically connected to the base circuit element. The core circuit elements are composed of a plurality of metal-oxide-semiconductors arranged in a matrix and a metal interconnection for electrically connecting the metal-oxide-semiconductors.

The present invention then proposes a programmable array module. The programmable array module includes a base circuit element and a plurality of core circuit elements. The base circuit element includes a memory cell, a processor, a control circuit and an interface circuit. The plurality of core circuit elements are stacking over and electrically connected to the base circuit element. The core circuit elements are composed of a plurality of metal-oxide-semiconductors arranged in a matrix and a metal interconnection for electrically connecting the metal-oxide-semiconductors.

The present invention again proposes a programmable array module. The programmable array module includes a base circuit element and a plurality layer of field programmable gate arrays. The base circuit element includes an interface circuit. The plurality layers of field programmable gate arrays are stacking over and electrically connected to the base circuit element.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a preferred example of the programmable array module of the present invention.

FIG. 2 illustrates another preferred example of the base circuit element of the present invention.

FIG. 3 illustrates an example of the single layer field programmable gate array of the present invention.

FIG. 4 illustrates an example of the multiple layers of stacking core circuits of the present invention.

### DETAILED DESCRIPTION

The present invention provides a novel programmable array module. A plurality of core circuit elements which merely includes a plurality of metal-oxide-semiconductors and a metal interconnection are stacking over and electrically connected to a base circuit element so that the undesirable defected elements certainly occurred in the production can no longer interfere with the operation of the novel programmable array module. The novel programmable array module of the present invention accordingly has dramatically high yield and low production cost to be advantageously competitive. In addition, another feature of stacking and electrically connecting a plurality of core circuit elements to a base circuit element is that as many as possible programmable logic gates can be accommodated in a limited chip area to magnify the compute ability of the novel programmable array module of the present invention as much as possible to be nearly optimal.

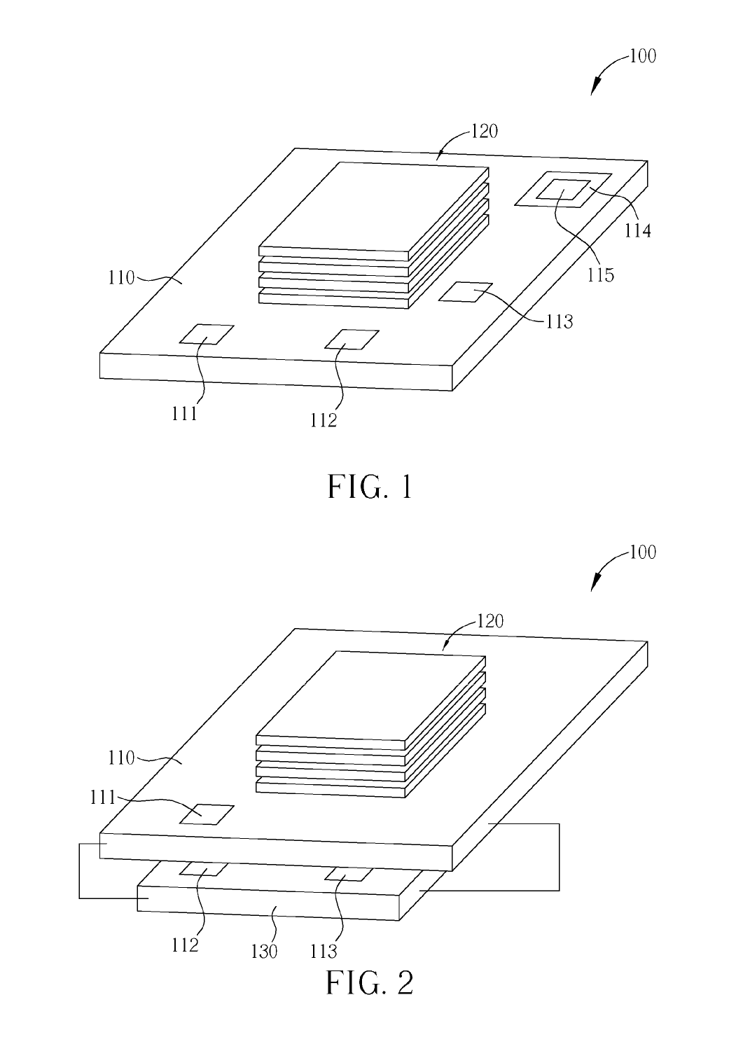

FIG. 1 illustrates a preferred example of the programmable array module of the present invention. The programmable array module 100 of the present invention includes two parts. The first part is a base circuit element 110 and the second part is a plurality of core circuit elements 120. The plurality of layer-stacking core circuit elements 120 are stacking over the base circuit element 110 and electrically connected to the base circuit element 110 so as to form the programmable array module 100 of the present invention.

In one embodiment of the present invention, the base circuit element 110 includes an interface circuit 111. A memory cell 112 or a processor 113 may be disposed internally or externally. As shown in FIG. 1, if the memory cell 112 and the processor 113 are internal, the base circuit element 110 includes a memory cell 112, a processor 113 and an interface circuit 111.

FIG. 2 illustrates another preferred example of the base circuit element 110 of the present invention. If the memory cell 112 and the processor 113 are external, the interface circuit 111 is further electrically connected to an external computer system 130. The computer system 130 may be directly disposed under the base circuit element 110 and is a computer element. The computer system 130 includes the memory cell 112 and the processor 113. No matter which embodiment is used, the base circuit element 110 of the present invention does not include a field programmable gate array.

Further, the base circuit element 110 of the present invention may further include a control circuit 114. The control circuit 114 may include a logic circuit 115. In other words, the base circuit element 110 of the present invention may include an interface circuit 111, a memory cell 112, a processor 113, and a control circuit 114 including a logic circuit 115.

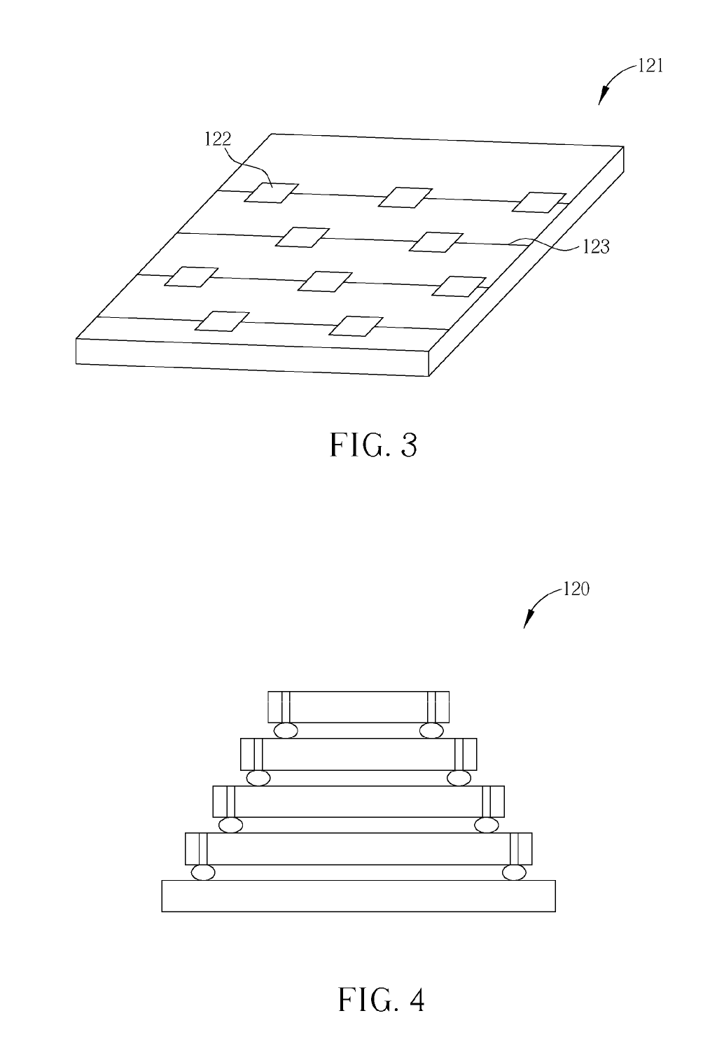

A plurality of core circuit elements 120 stacking over the base circuit element 110 are usually presented in multi-layer form, and layers are electrically connected to each other. Specifically speaking, the core circuit elements 120 of the present invention may be the field programmable gate arrays 121. FIG. 3 illustrates an example of the single layer field programmable gate array of the present invention. Such field programmable gate arrays 121 are usually composed of a plurality of metal-oxide-semiconductors 122 arranged in a matrix and a metal interconnection 123 for electrically connecting the metal-oxide-semiconductors 122. Multiple metal-oxide-semiconductors 122 play the essential role in the field programmable gate arrays 121, namely the logic gates, and electrically connected by the metal interconnection 123.

In addition, the multiple core circuit elements 120 of the present invention stacking over the base circuit element 110 may have various embodiments. For instance, each layer of the multi-layer core circuit elements 120 may have the same shape, as shown in FIG. 1 or all have the same area. Or, FIG. 4 illustrates an example of the multiple layers of stacking core circuit elements of the present invention. The multiple layers of stacking core circuit elements 120 have different areas. In this embodiment, the stacking core circuit elements 120 have decreasing areas upwards, which may structurally resemble a pyramid. The multiple layers of stacking core circuit elements 120 of the same area or of different areas may be electrically connected to each other by means of wiring, flip chip, BGA or through-silicon via (TSV).

Please note that each single layer of the multiple layers of the stacking core circuit elements 120 does not have to be a single complete field programmable gate array (FPGA) chip and can come from a segment which is cut from a single complete field programmable gate array (FPGA) chip. A chip may be cut to form segments of different shapes. Accordingly, a chip may be specially cut to eliminate the defected element(s) and to be an array of non-regular specification. For example, a complete chip of 12 by 12 units may be divided into various dimensions such as 7*5, 6*6, 4*4, 3*3, 2*2, 1*1, 6*4, 6*3, 6*2, 6*1, 4*3, 4*2, 4*1, 3*2, 3*1, 2*1 . . . etc. The remainder useable segments of the field programmable gate arrays are stacked on one another to compose the programmable array module of needed number of logic gates. Proper division or dimension may on one hand eliminate the defected elements and on the other hand pursue the optimal useable area of the chips. Besides, although each single layer of core circuit elements 120 has less area, the total area increases due to the stacking structure, namely, the total gate count increases. In other words, the programmable array module of the present invention has better performance without increasing the surface area of the programmable array module.

In the novel programmable array module of the present invention, a plurality of core circuit elements which merely includes a plurality of metal-oxide-semiconductors and a metal interconnection are stacking over and electrically connected to a base circuit element which includes a interface circuit, a memory cell or a processor. In such way, the undesirable defected elements certainly occurred in the production can not interfere with the operation of the novel programmable array module. The novel programmable array module of the present invention still has dramatically high yield and low production cost to be advantageously competitive. In addition, another feature of stacking core circuit elements is that as many as possible programmable logic gates can be accommodated in a limited chip area to magnify the compute ability of the novel programmable array module of the present invention as much as possible to be nearly optimal.

Those skilled in the art will readily observe that numerous modifications and alterations of the device and method may be made while retaining the teachings of the invention.

1. A programmable array module, comprising:
a base circuit element, comprising an interface circuit; and
a plurality of core circuit elements, stacking over and electrically connected to said base circuit element, each of said core circuit elements consisting of a plurality of logic metal-oxide-semiconductors arranged in a matrix and a metal interconnection for electrically connecting said metal-oxide-semiconductors.

2. The programmable array module of claim 1, wherein said interface circuit is electrically connected to a computer system.

3. The programmable array module of claim 2, wherein said computer system is a computer element disposed under said base circuit element.

4. The programmable array module of claim 2, wherein said computer system comprises a memory cell and a processor.

5. The programmable array module of claim 1, wherein said base circuit element further comprises a control circuit.

6. The programmable array module of claim 5, wherein said control circuit comprises a logic circuit.

7. The programmable array module of claim 1, wherein said core circuit elements comprise a field programmable gate array.

8. The programmable array module of claim 7, wherein said core circuit elements have different areas.

9. The programmable array module of claim 8, wherein said core circuit elements have decreasing areas.

10. The programmable array module of claim 7, wherein said core circuit elements have the same area.

11. A programmable array module, comprising:
a base circuit element, comprising a interface circuit; and
a plurality layer of field programmable gate arrays stacking over and electrically connected to said base circuit element.

12. The programmable array module of claim 11, wherein said plurality layers of field programmable gate arrays are electrically connected to a computer system.

13. The programmable array module of claim 12, wherein said computer system is a computer element disposed under said base circuit element.

14. The programmable array module of claim 12, wherein said computer system comprises a memory cell and a processor.

15. The programmable array module of claim 11, wherein said base circuit element further comprises a control circuit.

16. The programmable array module of claim 15, wherein said control circuit comprises a logic circuit.

17. The programmable array module of claim 11, wherein said plurality layer of field programmable gate arrays comprise a plurality of metal-oxide-semiconductors arranged in a matrix and a metal interconnection for electrically connecting said metal-oxide-semiconductors.

18. The programmable array module of claim 17, wherein said plurality layer of field programmable gate arrays have different areas.

19. The programmable array module of claim 18, wherein said plurality layer of field programmable gate arrays have decreasing areas.

20. The programmable array module of claim 17, wherein said plurality layer of field programmable gate arrays have the same area.
